(19) United States
(12) Patent Application Publication
(10) Pub. No.: US 2026/0123325 A1
(43) Pub. Date: Apr. 30, 2026

(54) SUBSTRATE PROCESSING METHOD, MANUFACTURING METHOD, AND SUBSTRATE PROCESSING APPARATUS

(71) Applicant: SEMES CO., LTD., Cheonan-si (KR)

(72) Inventors: Anton KORIAKIN, Suwon-si (KR); Joon Ho WON, Suwon-si (KR); Hyung Seok KANG, Suwon-si (KR); Pil Kyun HEO, Yongin-si (KR)

(73) Assignee: SEMES CO., LTD., Cheonan-si (KR)

(21) Appl. No.: 19/372,465

(22) Filed: Oct. 29, 2025

(30) Foreign Application Priority Data
Oct. 29, 2024 (KR) 10-2024-0149995

(51) Int. Cl. H01L 21/67

(52) U.S. Cl. CPC H10P 72/0404

(57) ABSTRACT

Provided is a method of processing a substrate. The method includes: a liquid treating operation of supplying a treatment liquid to the substrate; a drying operation of removing the treatment liquid supplied in the liquid treating operation from the substrate; and a line width correcting operation of correcting a line width of a pattern formed on the substrate in the liquid treating operation, in which the line width correcting operation includes correcting the line width of the pattern by supplying the treatment liquid to a treatment space in which the substrate is provided, but controlling a pressure of the treatment space to a pressure capable of maintaining the treatment fluid in a supercritical or subcritical state.

### CROSS-REFERENCE TO RELATED APPLICATION

This application claims priority to and the benefit of Korean Patent Application No. 10-2024-0149995 filed in the Korean Intellectual Property Office on Oct. 29, 2024, the entire contents of which are incorporated herein by reference.

### TECHNICAL FIELD

The present invention relates to a substrate processing method, a manufacturing method, and a substrate processing apparatus, and more specifically, to a substrate processing method, a manufacturing method, and a substrate processing apparatus that manufacture a semiconductor device.

### BACKGROUND ART

In order to manufacture a semiconductor device, various processes are performed on a substrate, such as a wafer. For example, in order to manufacture a semiconductor device, a cleaning process of cleaning a substrate, an applying process of applying a photosensitive film on the substrate, an exposure process of irradiating the photosensitive film with light, a developing process of supplying a developing liquid to the light-irradiated photosensitive film and forming a pattern through the photosensitive film, an etching process of removing the film on the substrate using the formed pattern as a mask, and an ashing process of removing the pattern that has performed the mask function from the substrate after the etching process may be performed. The above processes are implemented under various processing conditions depending on the type and function of the semiconductor device to be manufactured.

Meanwhile, the type and function of semiconductor devices vary depending on the shape of the circuit pattern implemented on the wafer. The shape of the circuit pattern may be determined by the exposure mask used in the exposure process. The exposure mask is a kind of ‘frame’. In the exposure process, a pattern is drawn on a photosensitive film applied on the substrate with light using an exposure mask. In the exposure process, an exposure mask is placed under a light source, and a substrate is placed under the exposure mask. Then, a light source emits light to the substrate through an exposure mask, and a circuit pattern is drawn on the photosensitive liquid film applied on the substrate.

The line width of the circuit pattern formed on the substrate varies according to the line width of the circuit pattern formed on the exposure mask. Therefore, when the line width of the circuit pattern formed on the substrate is different from the target line width or the target line width is to be changed, a new exposure mask must be manufactured accordingly. Recently, as the line width of a circuit pattern formed on a substrate becomes very fine, high precision is required to manufacture an exposure mask. Therefore, in the case of newly manufacturing an exposure mask to change the line width of a circuit pattern, it is inefficient because it takes a lot of cost and time.

### SUMMARY OF THE INVENTION

The present invention has been made in an effort to provide a substrate processing method, a manufacturing method, and a substrate processing apparatus that are capable of effectively processing a substrate.

The present invention has also been made in an effort to provide a substrate processing method, a manufacturing method, and a substrate processing apparatus that are capable of correcting a line width of a pattern formed on a substrate.

The present invention has also been made in an effort to provide a substrate processing method, a manufacturing method, and a substrate processing apparatus that are capable of minimizing the cost and time required to manufacture a new exposure mask.

The objectives of the present disclosure are not limited thereto and other objectives not stated herein may be clearly understood by those skilled in the art from the following description.

An exemplary embodiment of the present disclosure, a method of processing a substrate, the method comprising: a liquid treating operation of supplying a treatment liquid to the substrate; a drying operation of removing the treatment liquid supplied in the liquid treating operation from the substrate; and a line width correcting operation of correcting a line width of a pattern formed on the substrate in the liquid treating operation, wherein the line width correcting operation may includes correcting the line width of the pattern by supplying the treatment liquid to a treatment space in which the substrate is provided, but controlling a pressure of the treatment space to a pressure capable of maintaining the treatment fluid in a supercritical or subcritical state.

An exemplary embodiment of the present disclosure, a manufacturing method, wherein carbon dioxide is supplied to a treatment space where a substrate may be processed to control a pressure of the treatment space to be a high-pressure state, but the pressure of the treatment space is adjusted so that a line width of a pattern formed on the substrate is corrected based on a pre-measured pattern line width correction requirement value.

An exemplary embodiment of the present disclosure, an apparatus for processing a substrate, the apparatus comprising: a liquid treating chamber for supplying a treatment liquid to a substrate; at least one high-pressure chamber for supplying a treatment fluid to the substrate; and a controller, wherein the controller controls the liquid treating chamber and the high-pressure chamber to: supply the treatment liquid from the liquid treating chamber to the substrate; remove the treatment liquid supplied onto the substrate in any one of the liquid treating chamber and the high-pressure chamber; and after the treatment liquid is removed from the substrate, supply the treatment fluid from the high-pressure chamber to the substrate to may correct the line width on the substrate.

According to the exemplary embodiment of the present invention, it is possible to effectively process the substrate.

In addition, according to the exemplary embodiment of the present invention, it is possible to correct a line width of a pattern formed on a substrate.

In addition, according to the exemplary embodiment of the present invention, it is possible to minimize the cost and time required to manufacture a new exposure mask.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a top plan view schematically illustrating a substrate processing apparatus according to an exemplary embodiment of the present invention.

FIG. 2 is a diagram schematically illustrating a liquid treating chamber of FIG. 1.

FIG. 3 is a diagram schematically illustrating a high-pressure chamber of FIG. 2.

FIG. 4 is a flowchart illustrating a substrate processing method according to an exemplary embodiment of the present invention.

FIG. 5 is a diagram schematically illustrating a state of a substrate to be inspected when a line width measuring operation of FIG. 4 is performed.

FIG. 6 is a diagram illustrating a state of the liquid treating chamber performing a liquid treating operation of FIG. 4.

FIG. 7 is a graph illustrating a pressure change in the high-pressure chamber when the drying operation of FIG. 4 is performed.

FIGS. 8 to 10 are diagrams illustrating the state of the high-pressure chamber which performs a drying operation of FIG. 7.

FIG. 11 is a graph illustrating a pressure change in the high-pressure chamber when performing a line width correcting operation of FIG. 4.

FIG. 12 is a diagram illustrating the state of the high-pressure chamber performing the line width correcting operation of FIG. 4.

FIG. 13 is a graph illustrating a change in a pattern line width formed on the substrate when the line width correcting operation is performed.

FIGS. 14 to 16 are graphs illustrating the state in which a line width of a pattern formed on the substrate is corrected.

FIG. 17 is a graph illustrating a change in the pattern line width formed on the substrate according to a pressure change of the high-pressure chamber after a development process for the substrate is completed.

FIG. 18 is a graph illustrating a change in the pattern line width formed on the substrate according to a change in pressure of the high-pressure chamber after an etching process on the substrate is completed.

FIG. 19 is a graph illustrating another embodiment of a change in pressure in the high-pressure chamber when performing the drying operation of FIG. 4.

FIGS. 20 to 21 are diagrams illustrating the state of the high-pressure chamber which performs the drying operation of FIG. 19.

FIGS. 22 to 25 are graphs illustrating embodiments of a change in pressure in the high-pressure chamber when performing the drying operation and the line width correcting operation of FIG. 4 in one high-pressure chamber.

FIG. 26 is a diagram illustrating a state of the liquid treating chamber performing the drying operation of FIG. 4.

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

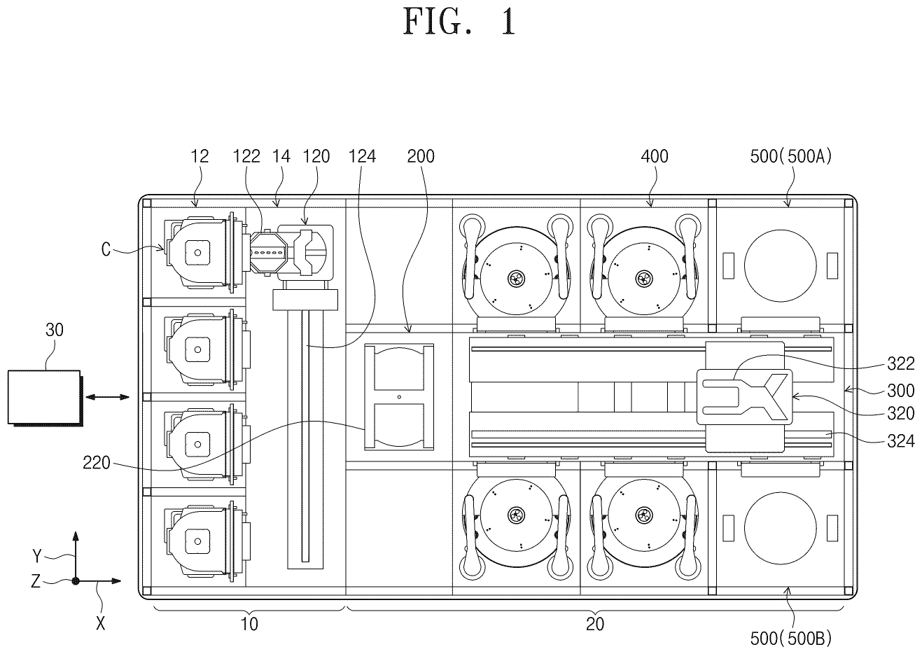

FIG. 1 is a top plan view schematically illustrating a substrate processing apparatus according to an exemplary embodiment of the present invention.

Referring to FIG. 1, a substrate processing apparatus includes an index module 10, a treating module 20, and a controller 30. When viewed from above, the index module 10 and the treating module 20 are disposed along one direction. Hereinafter, the direction in which the index module 10 and the treating module 20 are disposed is referred to as a first direction X, and when viewed from above, a direction perpendicular to the first direction X is referred to as a second direction Y, and a direction perpendicular to both the first direction X and the second direction Y is referred to as a third direction Z.

The index module 10 transfers a substrate W from a container C in which the substrate W is accommodated to the treating module 20, and makes the substrate W, which has been completely processed in the treating module 20, be accommodated in the container C. A longitudinal direction of the index module 10 is provided in the second direction Y. The index module 10 includes a load port 12 and an index frame 14. Based on the index frame 14, the load port 12 is located at a side opposite to the treating module 20. The container C in which the substrates W are accommodated is placed in the load port 12. The plurality of load ports 12 may be provided, and may be disposed in the second direction Y.

As the container C, an airtight container, such as a Front Open Unified Pod (FOUP), may be used. The container C may be placed on the load port 12 by a transfer means (not illustrated), such as an overhead transfer, an overhead conveyor, or an automatic guided vehicle, or an operator.

An index robot 120 is provided to the index frame 14. A guide rail 124 of which a longitudinal direction is the second direction Y is provided within the index frame 14, and the index robot 120 may be provided to be movable on the guide rail 124. The index robot 120 includes a hand 122 on which the substrate W is placed, and the hand 122 may be provided to be movable forward and backward, rotatable about the third direction Z, and movable along the third direction Z. A plurality of hands 122 are provided to be spaced apart in the vertical direction, and the hands 122 may move forward and backward independently of each other.

The controller 30 may control the substrate processing apparatus. The controller 30 may include a process controller formed of a microprocessor (computer) that executes the control of the substrate treating apparatus, a user interface formed of a keyboard in which an operator performs a command input operation or the like in order to manage the substrate treating apparatus, a display for visualizing and displaying an operation situation of the substrate treating apparatus, and the like, and a storage unit storing a control program for executing the process executed in the substrate treating apparatus under the control of the process controller or a program, that is, a treating recipe, for executing the process in each component according to various data and treating conditions. Further, the user interface and the storage unit may be connected to the process controller. The processing recipe may be stored in a storage medium in the storage unit, and the storage medium may be a hard disk, and may also be a portable disk, such as a CD-ROM or a DVD, or a semiconductor memory, such as a flash memory.

The controller 30 may control the substrate processing apparatus to perform the substrate processing method described below.

The treating module 20 includes a buffer unit 200, a transfer chamber 300, a liquid treating chamber 400, and a high-pressure chamber 500. The buffer unit 200 provides a space in which the substrate W loaded into the treating module 20 and the substrate W unloaded from the treating module 20 stay temporarily.

The liquid treating chamber 400 performs a liquid treatment process (operation) of liquid-treating the substrate W by supplying a treatment liquid onto the substrate W. For example, the liquid treating chamber 400 may perform a cleaning process (operation) of cleaning the substrate W by supplying a cleaning liquid to the substrate W, or a developing process (operation) of removing at least a part of a photosensitive film on the substrate W by supplying a developing liquid DL to the substrate W. In addition, the liquid treating chamber 400 may perform so-called spin dry to dry the substrate W by stopping the supply of treatment liquid to the substrate W and rotating the substrate W at high speed.

The high-pressure chamber 500 may perform a drying process (operation) of removing a liquid remaining on the substrate W. The high-pressure chamber 500 may perform a drying process (operation) of removing a cleaning liquid or a developing liquid DL remaining on the substrate W by supplying carbon dioxide in a supercritical state to the substrate W. Also, the high-pressure chamber 500 may a line width correction process (operation) of supplying carbon dioxide in a supercritical, subcritical, or liquid state onto the substrate W, controlling the space in the high-pressure chamber 500 to a high-pressure state, and correcting a line width CD of a pattern PA formed on the substrate W through this.

A plurality of high-pressure chambers 500 may be provided. A plurality of high-pressure chambers 500A may include a first high-pressure chamber 500B and a second high-pressure chamber 500B. The first high-pressure chamber 500A and the second high-pressure chamber 500B may have the same structure. The drying process may be performed in the first high-pressure chamber 500A, and the line width correction process may be performed in the second high-pressure chamber 500B. Alternatively, both the drying process and the line width correction process may be performed in the first high-pressure chamber 500A and the second high-pressure chamber 500B. The first high-pressure chamber 500A and the second high-pressure chamber 500B may be disposed to face each other with the transfer chamber 300 interposed therebetween.

The transfer chamber 300 transfers the substrate W between the buffer unit 200, the liquid treating chamber 400, and the high-pressure chamber 500. The transfer chamber 300 may be provided so that a longitudinal direction is the first direction X. The buffer unit 200 may be disposed between the index module 10 and the transfer chamber 300. The liquid treating chamber 400 and the higher pressure chamber 500 may be disposed on a side portion of the transfer chamber 300. The liquid treating chamber 400 and the transfer chamber 300 may be disposed in the second direction Y. The high-pressure chamber 500 and the transfer chamber 300 may be disposed in the second direction Y. The buffer unit 200 may be located at one end of the transfer chamber 300.

According to an example, the liquid treating chambers 400 may be disposed on opposite sides of the transfer chamber 300, the high-pressure chambers 500 may be disposed on opposite sides of the transfer chamber 300, and the liquid treating chambers 400 may be disposed closer to the buffer unit 200 than the high-pressure chambers 500. At one side of the transfer chamber 300, the liquid treating chambers 400 may be provided in an array of A×B (each of A and B is 1 or a natural number larger than 1) in the first direction X and the third direction Z. Further, at one side of the transfer chamber 300, the high-pressure chambers 500 may be provided in a number of C×D (C and D are each 1 or a natural number larger than 1) may be provided along each of the first direction X and the third direction Z. Unlike the above description, only the liquid treating chambers 400 may be provided at one side of the transfer chamber 300, and only the high-pressure chambers 500 may be provided at the other side thereof.

The transfer chamber 300 includes a transfer robot 320. A guide rail 324 having a longitudinal direction in the first direction X is provided in the transfer chamber 300, and the transfer robot 320 may be provided to be movable on the guide rail 324. The transfer robot 320 includes a hand 322 on which the substrate W is placed, and the hand 322 may be provided to be movable forward and backward, rotatable about the third direction Z, and movable along the third direction Z. A plurality of hands 322 are provided to be spaced apart in the vertical direction, and the hands 322 may move forward and backward independently of each other.

The buffer unit 200 includes a plurality of buffers 220 on which the substrate W is placed. The buffers 220 may be disposed while being spaced apart from each other in the third direction Z. A front face and a rear face of the buffer unit 200 are opened. The front face is a face facing the index module 10, and the rear face is a face facing the transfer chamber 300. The index robot 120 may approach the buffer unit 200 through the front face, and the transfer robot 320 may approach the buffer unit 200 through the rear face.

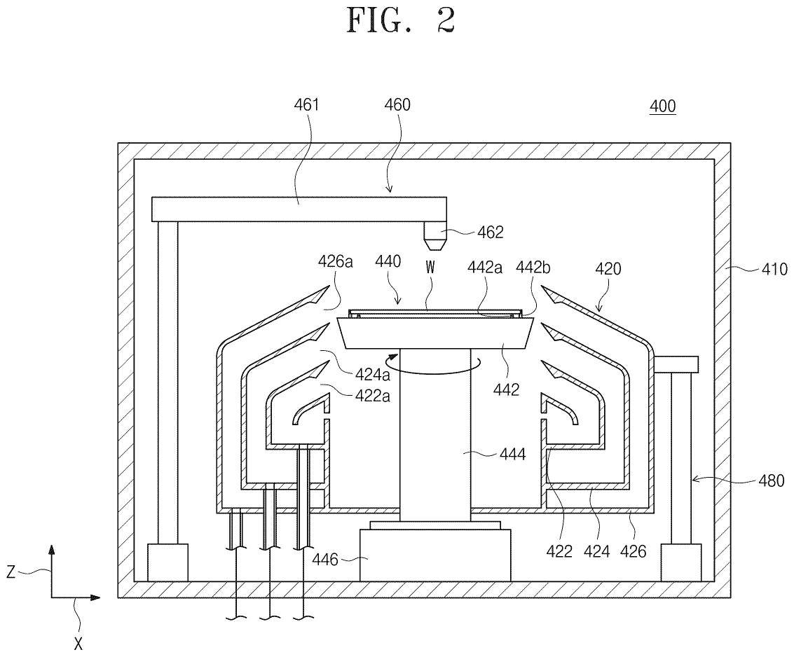

FIG. 2 is a diagram schematically illustrating the liquid treating chamber of FIG. 1.

Referring to FIG. 2, the liquid treating chamber 400 includes a housing 410, a cup 420, a support unit 440, a liquid supply unit 460, and a lifting unit 480.

The housing 410 may have an inner space in which the substrate W is processed. The housing 410 may have a substantially hexahedral shape. For example, the housing 410 may have a substantially rectangular parallelepiped shape. Further, an opening (not illustrated) through which the substrate W enters and exits is formed in the housing 410. Also, a door (not illustrated) for selectively opening and closing the opening may be installed in the housing 410.

The cup 420 may have a cylindrical shape with an open top. The cup 420 has a treatment space, and the substrate W is liquid-treated in the treatment space. The support unit 440 supports the substrate W in the treatment space. The liquid supply unit 460 supplies the treatment liquid onto the substrate W supported by the support unit 440. The treatment liquid may be provided in a plurality of types, and may be sequentially supplied onto the substrate W. The lifting unit 480 adjusts a relative height between the cup 420 and the support unit 440.

According to an example, the cup 420 includes a plurality of recovery containers 422, 424, and 426. Each of the recovery containers 422, 424, and 426 has a recovery space of recovering the liquid used for the processing of the substrate. Each of the recovery containers 422, 424, and 426 is provided in a ring shape surrounding the support unit 440. As the liquid treatment process proceeds, the treatment liquid scattered by the rotation of the substrate W is introduced into the recovery space through the inlets 422a, 424a, and 426a of the respective recovery containers 422, 424, and 426. According to the example, the cup 420 includes a first recovery container 422, a second recovery container 424, and a third recovery container 426. The first recovery container 422 is disposed to surround the support unit 440, the second recovery container 424 is disposed to surround the first recovery container 422, and the third recovery container 426 is disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 440 includes a support plate 442 and a drive shaft 444. An upper surface of the support plate 442 may be provided in a generally circular shape, and may have a diameter larger than a diameter of the substrate W. Further, a support pin 442a supporting the rear surface of the substrate W is provided at the center of the support plate 442, and the upper end of the support pin 442a is provided to protrude from the support plate 442 so that the substrate W is spaced apart from the support plate 442 by a predetermined distance. A chuck pin 442b is provided at an edge portion of the support plate 442. The chuck pin 442b is provided to protrude upward from the support plate 442, and supports the side portion of the substrate W so that the substrate W does not deviate from the support unit 440 when the substrate W is rotated. The drive shaft 444 is driven by the driver 446, is connected to the center of the bottom surface of the substrate W, and rotates the support plate 442 about its central axis.

According to an example, the liquid supply unit 460 may include a nozzle 462. The nozzle 462 may supply a treatment liquid to the substrate W. The treatment liquid may be a cleaning liquid or a developing liquid DL. The cleaning liquid may be a chemical, such as SC-1 or DHF. Also, the cleaning liquid may be a rinse liquid, such as DIW, or an organic solvent, such as IPA. The developing liquid DL may remove a part of the photosensitive film on the exposed substrate W to form a pattern PA on the substrate W.

The lifting unit 480 moves the cup 420 in the up and down direction. By the up and down movement of the cup 420, a relative height between the cup 420 and the substrate W is changed. Accordingly, the recovery containers 422, 424, and 426 for recovering the treatment liquid are changed according to the type of liquid supplied to the substrate W, and thus the liquids may be separated and recovered. Unlike the description, the cup 420 may be fixedly installed, and the lifting unit 480 may move the support unit 440 in the vertical direction.

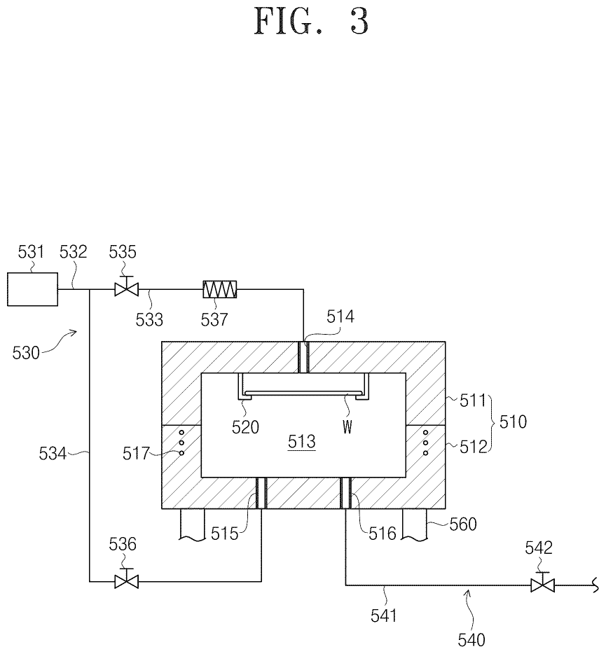

FIG. 3 is a diagram schematically illustrating a high-pressure chamber of FIG. 2.

Referring to FIG. 3, the drying chamber 500 according to the embodiment of the present invention may include a body 510, a support member 520, a fluid supply unit 530, a fluid exhaust unit 550, and a driver 560.

The body 510 may provide a treatment space 513 in which the substrate W is processed. The body 510 may include a first body 511 and a second body 512. The first body 511 and the second body 512 may be combined to be manufactured in a shape defining the treatment space 513. The first body 511 may be an upper body, and the second body 512 may be a lower body. One of the first body 511 and the second body 512 may move to open the treatment space 513 or close the treatment space 513.

For example, the first body 511 may be fixed, and the second body 512 may be moved in the up-down direction by the driver 560 that is moved by receiving power from a cylinder or a motor. The second body 512 may be moved in a direction closer to the first body 511 to close the treatment space 513. In addition, the second body 512 may move in a direction away from the first body 511 to open the treatment space 513.

Also, a first supply port 514 may be provided in the first body 511. The first supply port 514 may be a port formed by processing the first body 511. Alternatively, the first supply port 514 may be a port separately manufactured in a pipe shape and inserted into a hole formed in the first body 511. The first supply port 514 may supply a treatment fluid SCF to a central region of the upper surface of the substrate W placed on the support member 520 to be described later.

Also, a second supply port 515 and an exhaust port 516 may be provided in the second body 512. The second supply port 515 and the second exhaust port 516 may be ports formed by processing the second body 512. Alternatively, the second supply port 515 and the exhaust port 516 may be ports that are separately manufactured in a pipe shape and inserted into and installed in a hole formed in the second body 512. The second supply port 515 may supply the treatment fluid SCF to a lower region of the treatment space 513. The exhaust port 516 may exhaust the treatment fluid SCF supplied to the treatment space 513.

The heater 517 may be provided on the body 510. The heater 517 may be provided in the body 510 to increase the temperature of the treatment space 513. The heater 517 may increase the temperature of the treatment space 513 to a temperature at which the treatment fluid SCF may maintain a supercritical state. The heater 517 may be installed in both the first body 511 and the second body 512, or may be installed in any one of the first body 511 and the second body 512. As an example, FIG. 3 illustrates that the heater 517 is buried in the second body 512. The heater 517 may be variously modified with a known heater, such as a resistive coil, capable of increasing the temperature of the treatment space 513.

The support member 520 may support the substrate W in the treatment space 513. The support member 520 may be installed on the lower surface of the first body 511 and configured to support an edge region of the substrate W. For example, one end of the support member 520 may include a fixing portion installed on the lower surface of the first body 511 and extending in an up-down direction, and a support portion extending in a horizontal direction from the fixing portion. The fixing portion and the support portion may be provided as a single body, or may be provided as separate bodies to be combined with each other.

In the above-described example, the present invention has been described based on the case where the support member 520 installed on the lower surface of the first body 511 as an example, but the support member may be installed on the second body 512.

The fluid supply unit 530 may supply the treatment fluid SCF to the treatment space 513. The treatment fluid SCF supplied by the fluid supply unit 530 to the treatment space 513 may include carbon dioxide. The treatment fluid SCF supplied by the fluid supply unit 530 to the treatment space 513 may be supplied to the treatment space 513 in a subcritical or supercritical state, or may be supplied to the treatment space 513 to be converted from a liquid or gas state to a subcritical or supercritical state.

The fluid supply unit 530 may include a fluid supply source 531, a main supply line 532, a first supply line 533, a second supply line 534, a first supply valve 535, a second supply valve 536, and a line heater 537.

The fluid supply source 531 may store and supply the treatment fluid SCF. The fluid supply source 531 may include a tank for storing the treatment fluid SCF, a flow rate control device for withdrawing the treatment fluid SCF at a set supply flow rate per unit time from the tank, and the like.

The main supply line 532 is connected to the fluid supply source 531, and may branch to the first supply line 533 and the second supply line 534. The first supply line 533 may supply the treatment fluid SCF to the upper region (an example of a first region) of the treatment space 513 through the first supply port 514. The second supply line 534 may supply the treatment fluid SCF to the lower region (an example of a second region) of the treatment space 513 through the second supply port 515.

A first supply valve 535, which may be an auto valve (opening and closing valve), is installed in the first supply line 533, and it is possible to select whether to supply the treatment fluid SCF to the first supply port 514 according to the opening and closing of the first supply valve 535. In addition, a line heater 537 for increasing the temperature of the treatment fluid SCF flowing through the first supply line 533 is installed in the first supply line 533, so that the line heater 537 may help the treatment fluid SCF to be converted to a supercritical state or maintained in a supercritical state by increasing the temperature of the treatment fluid SCF. In addition, the line heater 537 may be installed on the first supply line 533 and may be installed downstream from the first supply valve 535.

A second supply valve 536, which may be an auto valve (opening and closing valve), is installed in the second supply line 534, and it is possible to select whether to supply the treatment fluid SCF to the second supply port 515 according to the opening and closing of the second supply valve 536.

In the above-described example, the present invention has been described that the first supply valve 535 and the second supply valve 536 are auto valves as an example, but the present invention is not limited thereto, and the first and second supply valves 535 and 536 may be provided as flow control valves capable of adjusting the supply flow rate of the treatment fluid SCF.

The fluid exhaust unit 540 may exhaust the atmosphere of the treatment space 513. The fluid exhaust unit 540 may include an exhaust line 541 and an exhaust valve 542. The exhaust line 541 may be connected to a depressurizing device, such as a pump, which is not illustrated. The exhaust valve 542 may be an auto valve (opening and closing valve). The exhaust valve 542 may be installed on the exhaust line 541, and may be installed downstream from a point at which a first circulation line 551 and the exhaust line 541 are to be described later are connected. The atmosphere of the treatment space 513 may be selectively exhausted according to opening and closing of the exhaust valve 542.

The pressure of the treatment space 513 may vary according to a supply flow rate per unit time of the treatment fluid SCF supplied by the fluid supply unit 530 and an exhaust flow rate per unit time exhausted by the fluid exhaust unit 540.

A cleaning liquid or a developing liquid DL remaining on the substrate W may be removed from the high-pressure chamber 500. In addition, the high-pressure chamber 500 may correct the line width CD of the pattern PA formed on the substrate W.

Hereinafter, a substrate processing method according to an exemplary embodiment of the present invention will be described. The controller 30 may control the configurations of the substrate processing apparatus to perform the substrate processing method described below. Also, hereinafter, the present invention will be described based on the case where a drying operation S30 and a line width correcting operation S40 are performed in different high-pressure chambers 500 as an example. However, the present invention is not limited thereto, and the drying operation S30 and the line width correcting operation S40 may be performed in one high-pressure chamber 500. Also, the drying operation S30 may be performed in the liquid treating chamber 400, and the line width correcting operation S40 may be performed in the high-pressure chamber 500.

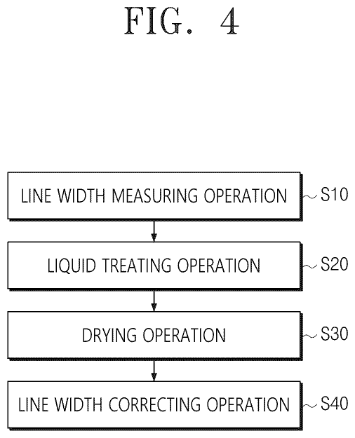

FIG. 4 is a flowchart illustrating a substrate processing method according to an exemplary embodiment of the present invention.

Referring to FIG. 4, a substrate processing method according to an embodiment of the present invention may include a line width measuring operation S10, a liquid treating operation S20, a drying operation S30, and a line width correcting operation S40. The line width measuring operation S10, the liquid treating operation S20, the drying operation S30, and the line width correcting operation S40 may be sequentially performed.

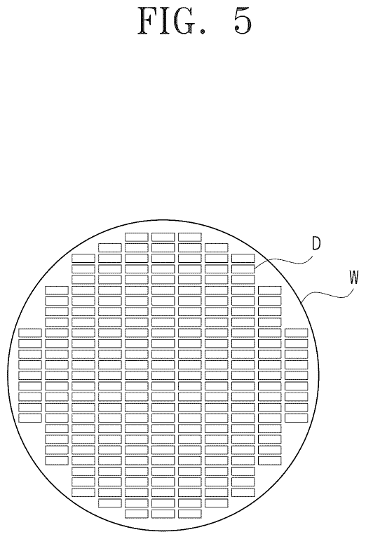

FIG. 5 is a diagram schematically illustrating a state of a substrate to be inspected when the line width measuring operation of FIG. 4 is performed.

Referring to FIGS. 4 and 5, a die D may be provided on the substrate W to be inspected. The die D refers to a small square piece of a semiconductor material, and a circuit may be manufactured thereon. In general, several integrated circuits are generated on one substrate W. And, the substrate W is cut and divided into several pieces, and each piece may contain one integrated circuit.

The user may measure the line width of a circuit of the plurality of dies D provided on the substrate W. The substrate W used in the line width measuring operation S10 may be a test substrate for measuring a line width that varies according to a change in process conditions. When manufacturing a circuit of a plurality of dies D provided on the substrate W, applied process conditions may be different. For example, the intensity of light emitted to each of the dies D during the exposure process may be different. In addition, by inspecting the integrated circuit formed on each die D, the pattern line width and defects (e.g., pattern broken and pattern bridge) that may occur while the pattern is formed may be identified.

The above inspection may be implemented by an inspector capable of inspecting the pattern of the die D on the substrate W. The inspector may be a Scanning Electron Microscope (SEM) inspection equipment. However, the present invention is not limited thereto, and the type of inspector may be variously modified into a known device capable of inspecting a pattern formed on the substrate W.

When the user forms the pattern PA on the substrate W through the line width inspection operation S10, the user may check a process condition having the lowest probability of defects, such as the above-described pattern broken and pattern bridge, occurring.

The line width CD of the pattern PA formed on the substrate W may vary depending on the line width of the pattern formed on the exposure mask used in the exposure process and the intensity of light emitted to the substrate W during the exposure process. Since the exposure mask is provided rigidly, its shape is not substantially changed. Accordingly, the process condition changed in the line width inspection operation S10 may be the intensity of light emitted during the exposure process. When the intensity of the light is increased, the line width CD may be decreased, and when the intensity of the light is decreased, the line width CD may be increased. When the line width CD is too small, defects, such as pattern broken, may occur, and when the line width CD is too large, defects, such as pattern bridge, may occur.

Therefore, in the line width inspection operation S10, a process condition (intensity of light) having the smallest probability of defects occurring with respect to a specific exposure mask and a line width CD of the pattern PA formed under this condition may be measured. However, in some cases, the line width CD (low defect line width) of the pattern PA formed under the process condition having the smallest probability of defects occurring may be different from the line width CD (target line width) of a target pattern PA. In other words, the line width CD of the pattern PA formed under the condition having the smallest probability of defects occurring may be different from the line width CD of the pattern PA that the user wants to form.

In general, in order to solve this problem, a new exposure mask needs to be manufactured. However, this method is very inefficient in terms of time and cost. Accordingly, the present invention provides a line width correction method capable of reducing a deviation between the line width CD formed under the condition having the smallest probability of a defect occurring and the line width CD to be formed by the user.

The controller 30 may store the above-described deviation value and the processing condition capable of minimizing the deviation value in advance. The processing condition may be a condition, such as a pressure and/or temperature in the treatment space 513 of the high-pressure chamber 500 to be described later. The processing condition may be a condition set in advance by the user through an experiment. The pressure of the treatment space 513 (an example of a processing condition) in the line width correcting operation S40 to be described later may be determined based on a correction requirement value for the line width CD requiring correction. The correction requirement value may be a deviation between the above-described low defect line width and the target line width.

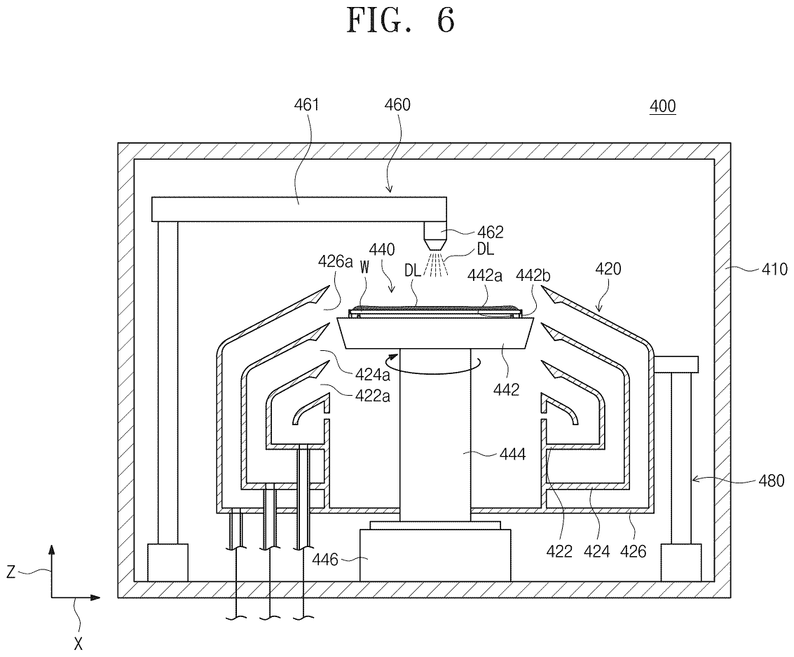

FIG. 6 is a diagram illustrating a state of the liquid treating chamber performing the liquid treating operation of FIG. 4.

Referring to FIGS. 4 and 6, in the liquid treating operation S20, the liquid supply unit 460 may supply the developing liquid DL to the substrate W supported by the support unit 440. The liquid treating operation S20 may be a developing process (operation). The substrate W loaded into the liquid treating chamber 400 may be the substrate W on which an applying process and an exposure process have been performed. In the applying process, a photoresist may be supplied to the rotating substrate W to form a photoresist film on the substrate W. In the exposure process, a pattern may be drawn by emitting light onto the substrate W on which the photoresist film is formed. In the exposure process, an exposure mask may be disposed between the light source and the substrate W, and a circuit pattern engraved on the exposure mask may be drawn through light emitted by the light source.

In the liquid treating operation S20, the support unit 440 may rotate the substrate W, and the liquid supply unit 460 may supply the developing liquid DL to the rotating substrate W. The developing liquid DL supplied to the substrate W may remove a portion irradiated with light or a portion not irradiated with light. That is, in the liquid treating operation S20, any one of the positive tone phenomenon and the negative tone phenomenon may be implemented.

When the liquid treating operation S20 is terminated, a pattern PA may be formed on the substrate W while at least a portion of the photosensitive liquid film provided on the substrate W is removed. The pattern PA may be a photoresist pattern. Also, when the liquid treating operation S20 is terminated, the developing liquid DL may remain on the substrate W in the form of a liquid layer. When the substrate W is transferred in a state in which the developing liquid DL on the substrate W is not completely dried, a water mark may be formed on the substrate W as the developing liquid DL on the substrate W is naturally dried. Accordingly, when the liquid treating operation S20 is terminated, the developing liquid DL may remain on the substrate W in the form of a liquid film, and the substrate W in this state may be transferred to the high-pressure chamber 500 to be described later.

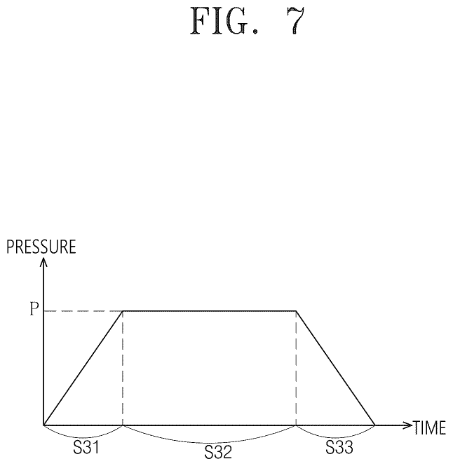

FIG. 7 is a graph illustrating a pressure change in the high-pressure chamber when the drying operation of FIG. 4 is performed.

Referring to FIGS. 4 and 7, in the drying operation S30, the developing liquid DL, which is the treatment liquid supplied onto the substrate W, may be removed from the substrate W. In the drying operation S30, the treatment liquid remaining on the substrate W may be removed to dry the substrate W. The drying operation S30 may be performed in the high-pressure chamber 500. The drying operation S30 may include a dry pressurizing operation S31, a flowing operation S32, and a drying depressurizing operation S33. The dry pressurizing operation S31, the flowing operation S32, and the drying depressurizing operation S33 may be sequentially performed. Hereinafter, the present invention will be described based on the case where the drying operation S30 is performed in the first high-pressure chamber 500A among the high-pressure chambers 500 as an example.

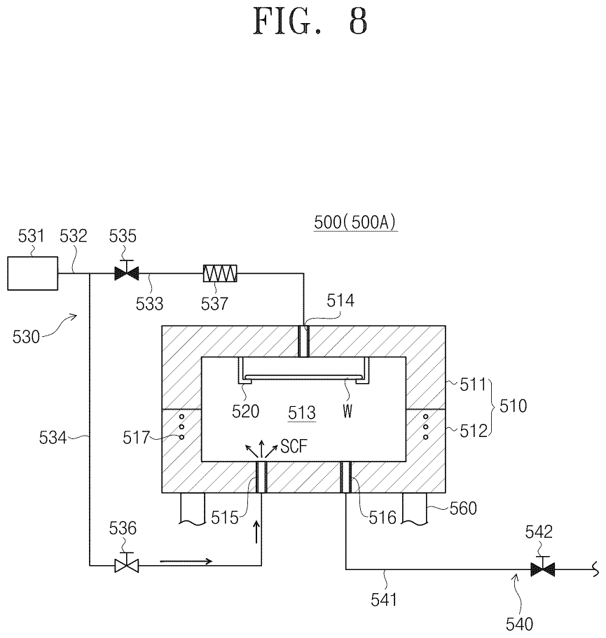

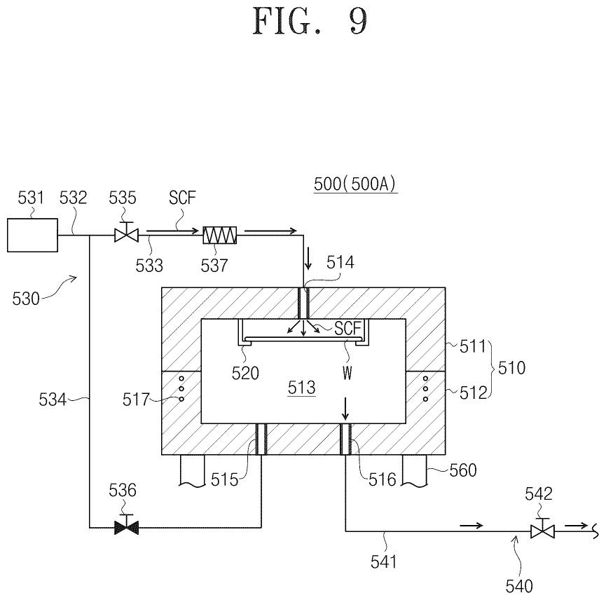

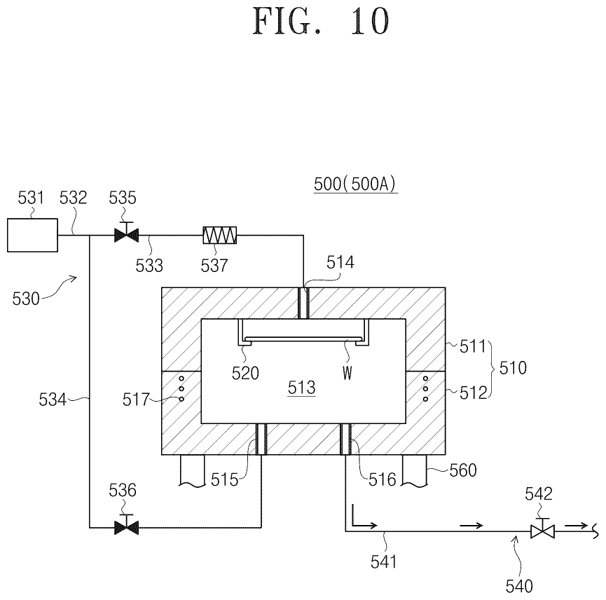

FIGS. 8 to 10 are diagrams illustrating the state of the high-pressure chamber which performs the drying operation of FIG. 7. FIG. 8 illustrates the first high-pressure chamber 500A performing the dry pressurizing operation S31, FIG. 9 illustrates the first high-pressure chamber 500A performing the flowing operation S32, and FIG. 10 illustrates the first high-pressure chamber 500A performing the drying depressurizing operation S33.

Referring to FIGS. 4, 7, and 8 to 10, in the dry pressurizing operation S31, the pressure in the treatment space 513 (an example of a first treatment space) of the first high-pressure chamber 500A may be increased. In the dry pressurizing operation S31, the substrate W may be loaded into the treatment space 513 and supported by the support member 520. In the dry pressurizing operation S31, the pressure in the treatment space 513 may be increased to a set pressure P. The set pressure P may be a pressure at which the treatment fluid SCF may maintain a supercritical state. The set pressure P may be a pressure higher than a critical pressure at which the treatment fluid SCF may maintain a supercritical state.

In the dry pressurizing operation S31, the second supply port 515 may supply the treatment fluid SCF. In this case, the first supply valve 535 and the exhaust valve 542 may be closed, and the second supply valve 536 may be opened. In the dry pressurizing operation S31, the second supply port 515 supplies the treatment fluid SCF from the lower portion of the substrate W. Accordingly, at a pressure equal to or lower than the set pressure P, the treatment fluid SCF may not be able to maintain a supercritical state. At this time, when the treatment fluid SCF is supplied to the top of the substrate W, the substrate W may not be properly dried, and damage may occur to the pattern PA formed on the substrate W.

In the flowing operation S32, the first supply port 514 may supply the treatment fluid SCF, and the exhaust port 516 may exhaust the atmosphere of the treatment space 513. In this case, the first supply valve 535 and the exhaust valve 542 may be opened, and the second supply valve 536 may be closed. The second supply valve 536 may be opened in the flowing operation S32 according to a user's selection.

In the flowing operation S32, the treatment fluid SCF supplied to the treatment space 513 may flow while maintaining the pressure of the treatment space 513 at the set pressure P. That is, the supply flow rate of the treatment fluid SCF per unit time may be matched with the exhaust flow rate. A method of continuously supplying and exhausting the treatment fluid SCF while maintaining a constant pressure in the treatment space 513 in the flowing operation S32 may be referred to as a continuous flow method. In this case, the treatment fluid SCF in the supercritical state may remove the developing liquid DL remaining in the substrate W based on the high penetration force with respect to the pattern PA. The developing liquid DL remaining in the substrate W may be dissolved in the treatment fluid SCF penetrating the pattern PA, and the treatment fluid SCF in which the developing liquid DL is dissolved may be removed from the substrate W. The treatment fluid SCF removed from the substrate W may be discharged to the outside of the first high-pressure chamber 500A through the exhaust port 516.

In the drying depressurizing operation S33, the pressure in the treatment space 513 may be converted from the set pressure P to atmospheric pressure. In the drying depressurizing operation S33, the first supply valve 535 and the second supply valve 536 may be closed, and the exhaust valve 542 may be opened. In the drying depressurizing operation S33, the pressure in the treatment space 513 may be converted to atmospheric pressure, and then the treatment space 513 may be opened to discharge the substrate W from the first high-pressure chamber 500A.

In this case, since the substrate W has been completely dried by the treatment fluid SCF, even when the substrate W is unloaded from the first high-pressure chamber 500A, the substrate W may be free from the risk of water mark generation due to natural drying. The substrate W unloaded from the first high-pressure chamber 500A may be loaded into the second high-pressure chamber 500B to perform the line width correcting operation S40 to be described later.

FIG. 11 is a graph illustrating a pressure change in the high-pressure chamber when performing the line width correcting operation of FIG. 4. In the line width correcting operation S40, the treatment fluid SCF may be supplied to the substrate W on which the drying of the substrate W has been completed in the drying operation S30 to correct the magnitude of the line width CD of the pattern PA formed on the substrate W. The line width correcting operation S40 may be performed in the high-pressure chamber 500. The line width correcting operation S40 may include a line width correction pressurizing operation S41, a pressure maintaining operation S42, and a line width correction depressurizing operation S43. The line width correction pressurizing operation S41, the pressure maintaining operation S42, and the line width correction depressurizing operation S43 may be sequentially performed. Hereinafter, the present invention will be described based on the case where the line width correcting operation S40 is performed in the second high-pressure chamber 500B as an example.

Hereinafter, the operation of the second high-pressure chamber 500B in the line width correction pressurizing operation S41 may be the same as or similar to the operation of the first high-pressure chamber 500A in the dry pressurizing operation S31 described above. Also, the operation of the second high-pressure chamber 500B in the line width correction depressurizing operation S43 may be the same as or similar to the operation of the first high-pressure chamber 500A in the drying depressurizing operation S33 described above. Thus, the repeated illustration of the drawing is omitted.

In the line width correction pressurizing operation S41, the pressure in the treatment space 513 (an example of a second treatment space) of the second high-pressure chamber 500B may be increased to a correction pressure PLvn. The correction pressure PLvn may be a pressure close to the above-described critical pressure. The correction pressure PLvn may be a pressure higher than the critical pressure or a pressure lower than the critical pressure. The correction pressure PLvn may be determined based on a required correction requirement value, based on the magnitude of the line width CD measured in the above-described line width measuring operation S31. For example, when the above-described correction requirement value is relatively small, the correction pressure PLvn may be relatively low, and when the above-described correction requirement value is relatively large, the correction pressure PLvn may be relatively large. For example, when the line width CD is corrected to a first magnitude, the correction pressure PLvn may be controlled to be a first pressure, and when the line width CD is corrected to a second magnitude larger than the first magnitude, the correction pressure PLvn may be controlled to be a second pressure greater than the first pressure.

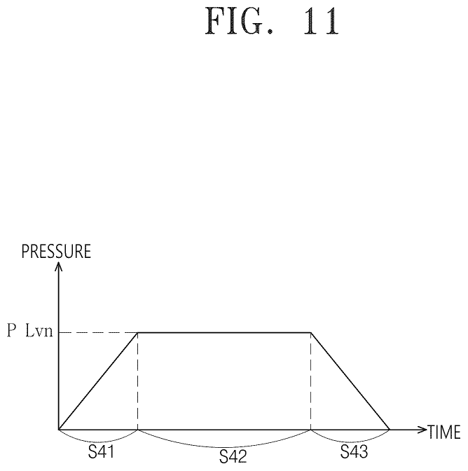

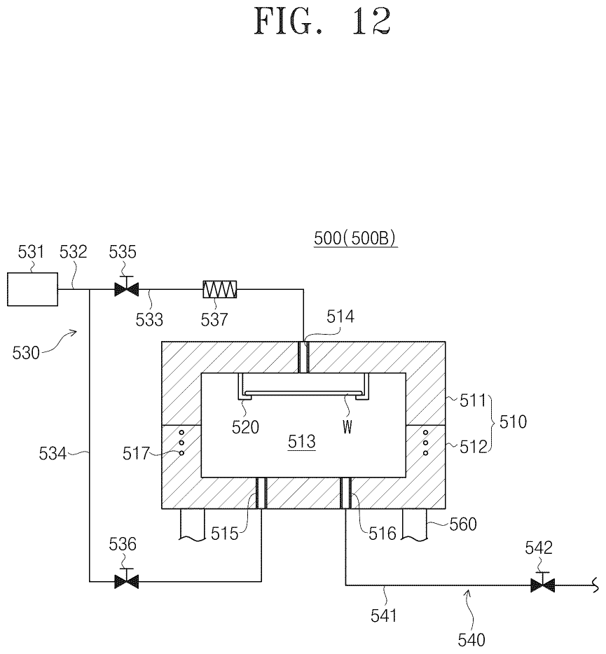

In the pressure maintaining operation S42, the pressure of the treatment space 513 may be constantly maintained. For example, in the pressure maintaining operation S42, the pressure of the treatment space 513 may be constantly maintained as the correction pressure PLvn. In the pressure maintaining operation S42, as illustrated in FIG. 12, the first supply valve 535, the second supply valve 536, and the exhaust valve 542 may all be closed. In the pressure maintaining operation S42, the pressure of the treatment space 513 may be constantly maintained as the correction pressure PLvn without exhausting the treatment space 513.

Since there is a need to remove the developing liquid DL from the substrate W and discharge the removed developing liquid DL to the outside of the first high-pressure chamber 500A in the flowing operation S32, the supply and exhaust of the treatment fluid SCF were performed in the flowing operation S32. However, the pressure maintaining operation S42 of the present invention may not be for drying the substrate W. The pressure maintaining operation S42 may be for correcting the line width CD of the pattern PA by supplying the treatment fluid SCF to the treatment space 513 and maintaining the pressure in the treatment space 513 as the correction pressure PLvn. Accordingly, unlike the flowing operation S32, in the pressure maintaining operation S42, the pressure in the treatment space 513 is constantly maintained as the correction pressure PLvn without supply and exhaust of the treatment fluid SCF.

Referring back to FIG. 11, in the line width correction depressurizing operation S43, similar to the dry depressurizing operation S33 described above, the pressure in the treatment space 513 may be converted from the correction pressure PLvn to the atmospheric pressure.

As described above, the drying operation S30 and the line width correcting operation S40 have different treatment conditions. For example, the supply and exhaust of the treatment fluid SCF are continued in the flowing operation S32 in the drying operation S30, but the supply and exhaust of the treatment fluid SCF are not performed in the pressure maintaining operation S42.

Meanwhile, the set pressure P of the flowing operation S32 and the correction pressure PLvn of the line width correcting operation S40 may be the same or different. However, there may be a difference in that the set pressure P is defined as the pressure for maintaining the supercritical sate of the treatment fluid SCF, whereas the correction pressure PLvn is a pressure determined by a line width correction requirement value.

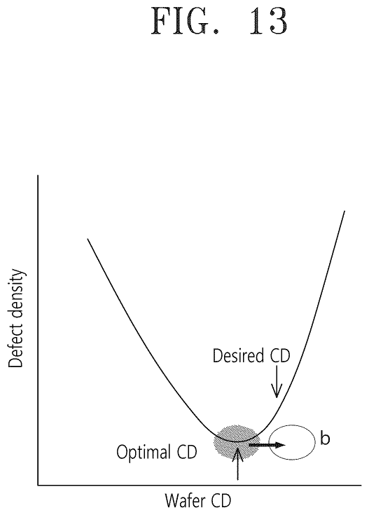

FIG. 13 is a graph illustrating a change in a pattern line width formed on the substrate when the line width correcting operation is performed.

Referring to FIG. 13, the magnitude of the line width CD of the pattern PA measured in the above-described line width measuring operation S10 is taken as the X axis, and the density (probability) of defects that may occur on the pattern PA is illustrated as the Y axis. As described above, while changing the intensity of light emitted to the substrate W during the exposure process, the line width CD of the pattern PA and the occurrence of defects are measured and illustrated as a graph. As illustrated in FIG. 13, the optimal line width Optimal CD may have the lowest probability of defects. Accordingly, when the substrate W is processed with the intensity of light implementing the optimum line width Optimal CD in the exposure process, the occurrence of defects, such as pattern bridge or pattern broken, may be minimized. However, in some cases, the optimum line width Optimal CD (low defect line width) may be different from a desired line width Desired CD (target line width). In order to solve this problem, a new exposure mask needs to be manufactured, but the present invention provides the substrate processing method and the manufacturing method of correcting a pattern PA manufactured with the optimum line width Optimal CD to a desired line width Desired CD. When using such a method, the magnitude of the line width CD of the pattern PA may be formed in a desired magnitude while lowering defects in the pattern PA manufactured in the exposure process as much as possible.

FIGS. 14 to 16 are graphs illustrating the state in which a line width of a pattern formed on the substrate is corrected.

Referring to FIG. 14, after the applying process (operation), the exposure process (operation), the development process (operation), and the drying process (operation) are sequentially performed, a pattern PA may be formed on the substrate W.

As illustrated in FIG. 14, before the line width correcting operation S40 is performed, the pattern PA formed on the substrate W may have the line width CD before correction.

Thereafter, as illustrated in FIG. 15, when the substrate W is loaded into the treatment space 513 and is placed in a high-pressure carbon dioxide environment, the carbon dioxide penetrates into the pattern PA formed of a photoresist, and the pattern PA may be expanded to have a line width CD′ during correction. In this case, the glass transition temperature of the polymer material constituting the photoresist may be reduced, so that the mobility of the polymer chain may be increased.

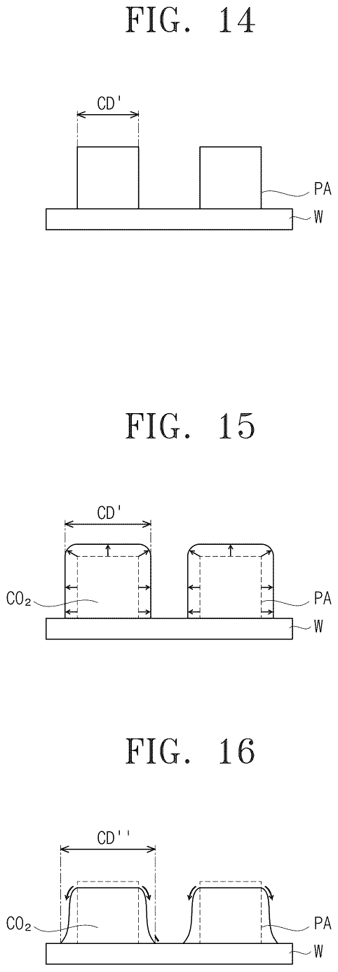

Due to the effect, the cross-section of the pattern PA may be changed in the shape illustrated in FIG. 16. Accordingly, after the line width correcting operation S40 is performed, the pattern PA formed on the substrate W may have a line width CD″ after correction.

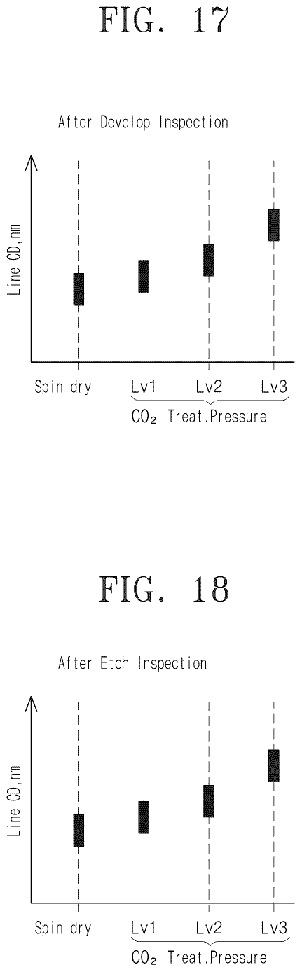

FIG. 17 is a graph illustrating a change in the pattern line width formed on the substrate according to a pressure change of the high-pressure chamber after the development process for the substrate is completed.

Referring to FIG. 17, when the substrate W on which the pattern PA is formed is placed in an environment of high-pressure carbon dioxide, and the change in the line width of the pattern PA is checked, it can be confirmed that when only spin-drying is performed without performing a separate line width correcting operation S40 on the substrate W, the line width CD of the pattern PA is the smallest. And, it may be confirmed that the higher the pressure by the treatment fluid (carbon dioxide, SCF) in the treatment space 513, the larger the line width CD. Therefore, the larger the above-described correction requirement value (i.e., the larger the difference between the low defect line width and the target line width), the larger the correction pressure PLvn applied to the line width correcting operation S40, thereby satisfying the above-described correction requirement value.

Meanwhile, correcting the line width CD of the pattern PA in the line width correcting operation S40 of the present invention is to reflect the corrected line width CD in the etching operation performed after the development process. Accordingly, the inventors of the present invention confirmed the line width of the pattern formed on the substrate W after completing the etching process. As illustrated in FIG. 18, it may be seen that the line width CD of the pattern PA corrected in the line width correcting operation S40 is also reflected in the etching process.

In the above-described example, the present invention has been described based on the case where the treatment fluid SCF flows in a so-called continuous flow method in which the pressure of the treatment space 513 is kept constant at a set pressure P in the flowing operation S32, but the present invention is not limited thereto.

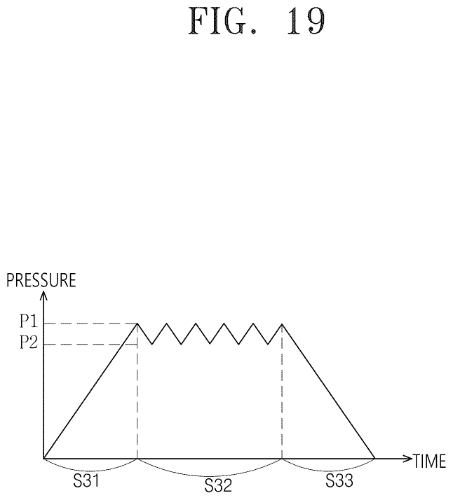

For example, as illustrated in FIG. 19, in the flowing operation S32, the pressure of the treatment space 513 may be pulsed between a first set pressure P1 and a second set pressure P2 lower than the first set pressure. Both the first set pressure P1 and the second set pressure P2 may be pressures higher than the threshold pressure. This method may be defined as a pressure pulsing method.

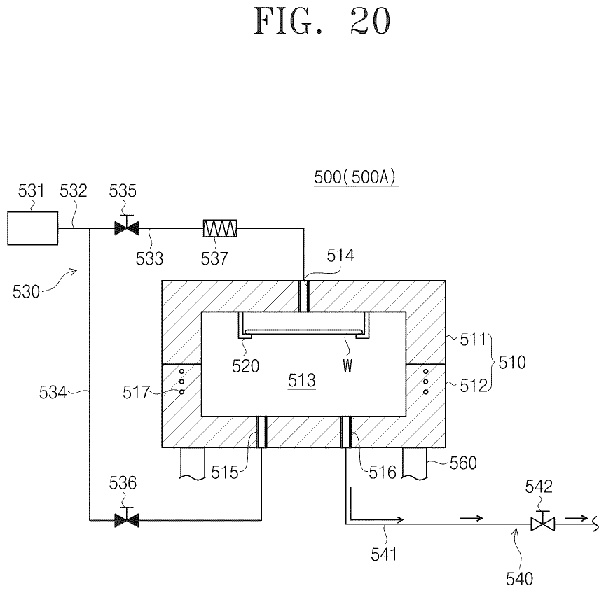

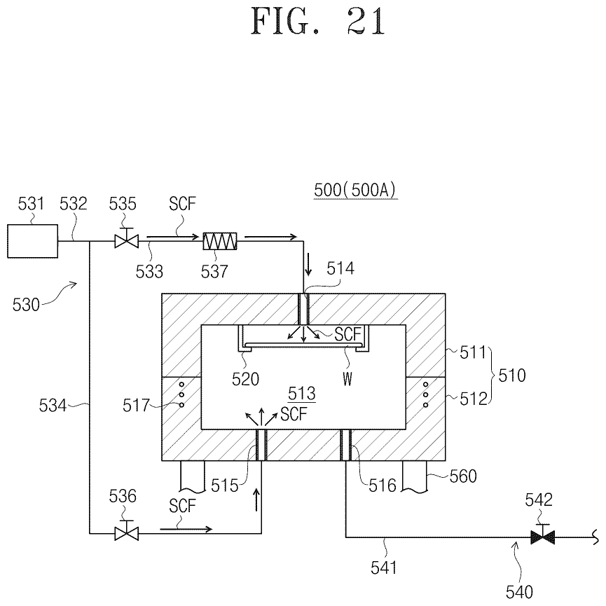

When the pressure is reduced from the first set pressure P1 to the second set pressure P2, the first and second supply valves 535 and 536 may be closed, and the exhaust valve 542 may be opened, as illustrated in FIG. 20. When the pressure is applied from the second set pressure P2 to the first set pressure P1, the first and second supply valves 535 and 536 may be opened, and the exhaust valve 542 may be closed, as illustrated in FIG. 21.

In the above-described example, the present invention has been described based on the case where the drying operation S30 and the line width correcting operation S40 are performed in the separate high-pressure chambers 500A and 500B as an example, but the present invention is not limited thereto.

For example, the drying operation S30 and the line width correcting operation S40 may be performed continuously in one high-pressure chamber 500 (i.e., when the first and second treatment spaces described above are the same space).

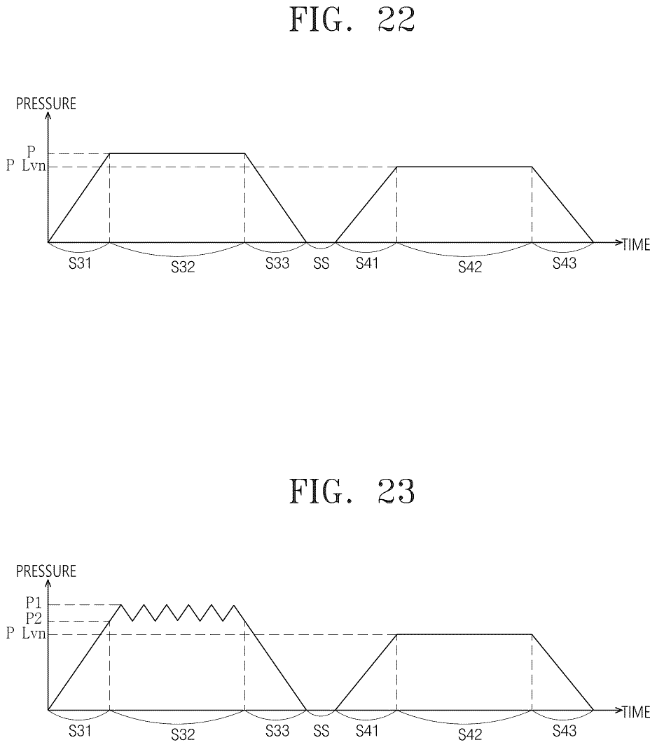

In this case, as illustrated in FIGS. 22 and 23, after the dry pressurizing operation S31, the flowing operation S32, and the dry depressurizing operation S33 are performed, the line width correction pressurizing operation S41, the pressure maintaining operation S42, and the line width correction depressurizing operation S43 may be performed.

In this case, after the developing liquid DL remaining on the substrate W is completely removed from the treatment space 513 by passing through the flowing operation S32 and the drying depressurizing operation S33, the line width correction pressurizing operation S41, the pressure maintaining operation S42, and the line width correction depressurizing operation S43 may be performed to correct the line width CD of the pattern PA on the substrate W. Also, as the substrate W is dried by the treatment fluid SCF in the drying operation S30, the pattern PA on the substrate W may be partially expanded. When the line width CD of the pattern PA of the substrate W is corrected in the state in which the pattern PA is expanded as described above, it may be difficult to properly perform the line width correction. Accordingly, by performing a standby operation SS between the drying depressurizing operation S33 and the line width correction pressurizing operation S41, it is possible to reduce the influence of the expansion of the pattern PA on the line width correction.

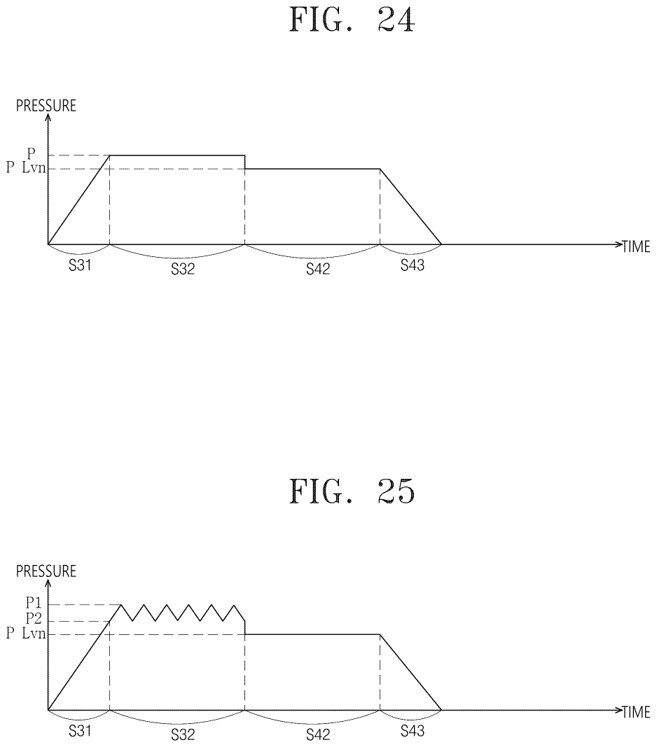

However, when the user selects the correction pressure PLvn in consideration of even the expansion of the pattern PA in the drying operation S30 described above, the drying depressurizing operation S33, the line width correction pressurizing operation S41, and the standby operation SS may be omitted as illustrated in FIGS. 24 and 25. In this case, the flowing operation S32 and the pressure maintaining operation S33 may be performed continuously.

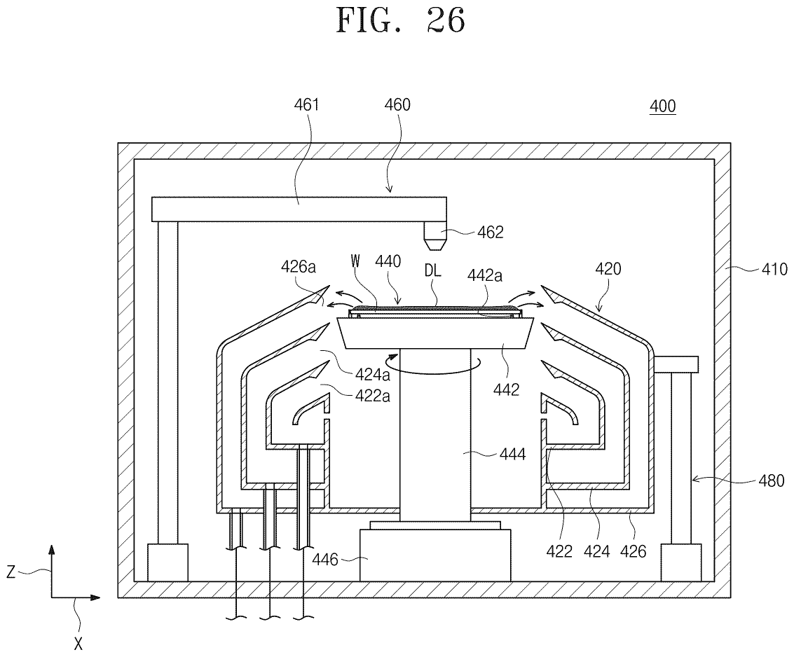

In the above-described example, the present invention has been described based on the case where the drying operation S20 is performed in the high-pressure chamber 500 as an example, but the present invention is not limited thereto. For example, as illustrated in FIG. 26, the drying operation S20 may also be performed in the liquid treating chamber 400.

In the above-described example, the present invention has been described based on the case where the line width correcting operation S30 is performed after the drying operation S20 is performed as an example, but the present invention is not limited thereto. For example, the drying operation S20 and the line width correcting operation S30 may be performed simultaneously in one high-pressure chamber 500. When the drying operation S20 and the line width correcting operation S30 are performed simultaneously, the correction pressure PLvn and the set pressure P may be the same pressure, and in this case, the correction pressure PLvn, and the time for which the drying operation S20 and the line width correcting operation S30 are performed may be determined based on the line width correction requirement value derived from the line width measuring operation S10.

It should be understood that exemplary embodiments are disclosed herein and other modifications may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present disclosure, and all such modifications that would be obvious to one of ordinary skill in the art are intended to be included within the scope of the accompanying claims.

1. A method of processing a substrate, the method comprising:
a liquid treating operation of supplying a treatment liquid to the substrate;
a drying operation of removing the treatment liquid supplied in the liquid treating operation from the substrate; and
a line width correcting operation of correcting a line width of a pattern formed on the substrate in the liquid treating operation,
wherein the line width correcting operation includes correcting the line width of the pattern by supplying the treatment liquid to a treatment space in which the substrate is provided, but controlling a pressure of the treatment space to a pressure capable of maintaining the treatment fluid in a supercritical or subcritical state.

2. The method of claim 1, wherein when the line width is to be corrected to a first magnitude, the pressure of the treatment space is controlled to a first pressure in the line width correcting operation, and
when the line width is to be corrected to a second magnitude larger than the first magnitude, the pressure of the treatment space is controlled to a second pressure greater than the first pressure in the line width correcting operation.

3. The method of claim 1, wherein in the line width correcting operation, the pressure of the treatment space is determined based on a correction requirement value for the line width.

4. The method of claim 1, wherein in the drying operation, the treatment fluid in the supercritical state is supplied to the substrate to remove the treatment liquid from the substrate, and
processing conditions of the drying operation and the line width correcting operation are different from each other.

5. The method of claim 3, wherein in the drying operation, the treatment fluid is supplied to a first treatment space for processing the substrate, and the treatment liquid on the substrate is removed while exhausting the first treatment space, and
in the line width correcting operation, the line width of the pattern is corrected by maintaining a pressure of the second treatment space as a correction pressure without exhausting the second treatment space, which is the treatment space.

6. The method of claim 5, wherein the drying operation includes:
a dry pressurizing operation of increasing a pressure of the first treatment space; and
a flowing operation of supplying the treatment fluid to the first treatment space and exhausting the first treatment space to allow the treatment fluid to flow in the first treatment space, and
the line width correcting operation includes:
a pressure maintaining operation of maintaining the pressure of the second treatment space as the correction pressure without exhausting the second treatment space; and
after the pressure maintaining operation, a line width correction depressurizing operation of reducing the pressure in the second treatment space.

7. The method of claim 6, wherein the drying operation further includes a drying depressurizing operation of reducing the pressure of the first treatment space after the flowing operation, and
the line width correcting operation further includes a line width correction pressurizing operation of increasing the pressure of the second treatment space.

8. The method of claim 7, wherein a standby operation is performed between the drying depressurizing operation and the line width correcting operation.

9. The method of claim 6, wherein the flowing operation and the pressure maintaining operation are performed continuously.

10. The method of claim 5, wherein the first treatment space and the second treatment space are the same space.

11. The method of claim 5, wherein the first treatment space and the second treatment space are different spaces.

12. The method of claim 1, wherein the drying operation includes rotating the substrate in a state where the substrate is supported on a support unit to remove the treatment liquid on the substrate after the liquid treating operation is completed.

13. The method of claim 2, further comprising:
a line width measuring operation of measuring a line width of a pattern formed on the substrate, the width measuring operation being performed before the liquid treating operation,
wherein the line width correcting operation includes determining the pressure of the treatment space based on a measurement value obtained in the line width measuring operation.

14. The method of claim 1, wherein after the line width correcting operation is completed, an etching operation is performed to remove a film on the substrate by using the pattern formed on the substrate as a mask.

15. The method of claim 1, wherein the treatment liquid is a developing liquid, and the treatment fluid contains carbon dioxide.

16. A manufacturing method, wherein carbon dioxide is supplied to a treatment space where a substrate is processed to control a pressure of the treatment space to be a high-pressure state, but the pressure of the treatment space is adjusted so that a line width of a pattern formed on the substrate is corrected based on a pre-measured pattern line width correction requirement value.

17. The manufacturing method of claim 16, wherein when the line width correction requirement value is small, the pressure of the treatment space is adjusted to a first pressure, and
when the line width correction requirement value is large, the pressure of the treatment space is adjusted to a second pressure greater than the first pressure.

18. The manufacturing method of claim 17, wherein the correction of the line width is performed after at least a part of the treatment liquid is removed from the substrate, and
the carbon dioxide supplied to the treatment space maintains a supercritical or subcritical state.

19-20. (canceled)
